(19) United States
(12) Patent Application Publication
(10) Pub. No.: US 2010/0024866 A1
(43) Pub. Date: Feb. 4, 2010

(54) SOLAR ENERGY CONCENTRATOR

(75) Inventors: Ravi Shankar Durvasula, Vancouver, WA (US); Charles Steven Korman, Niskayuna, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/183,084

(22) Filed: Jul. 31, 2008

(51) Int. Cl. H01L 31/042; H01L 31/00

(52) U.S. Cl. 136/246; 136/259

(57) ABSTRACT

A solar energy concentrator system comprises an optically transparent component, a bifacial solar cell situated within the optically transparent component and configured to intercept sunlight, a reflective component configured to reflect un-intercepted sunlight towards the bifacial solar cell, wherein the bifacial cell is configured to be positioned with a first surface facing sunlight and a second surface facing the reflective component.

### BACKGROUND

The subject matter disclosed herein relates generally to solar energy concentrators, and, more particularly, to static solar concentrators that harnesses off-angle sunlight using bifacial cells.

Static solar concentrators that operate in low sun concentrations, such as in the range of two suns to five suns, may be used to reduce the total solar cell area in a module (and thus the expense) while still producing a favorable level of power. Other solar concentrators typically use optical structures to focus highly concentrated light onto a solar cell. These optical structures perform well when exposed to direct sunlight but are less effective for off-angle sunlight. Therefore, mechanical tracking systems are used to control the angle of the optical structure with respect to the sun. In such embodiments, much of the cost of a module is associated with the mechanical tracking systems.

It would be desirable to increase optical efficiency without using mechanical tracking systems.

### BRIEF DESCRIPTION

In accordance with one embodiment disclosed herein, a solar energy concentrator system comprises an optically transparent component, a bifacial solar cell situated within the optically transparent component and configured to intercept sunlight, and a reflective component configured to reflect un-intercepted sunlight towards the bifacial solar cell. The bifacial cell is configured to be positioned with a first surface facing sunlight and a second surface facing the reflective component.

In accordance with another embodiment disclosed herein, a solar energy concentrator system comprises an optically transparent component, bifacial solar cells arranged in an array, situated in the optically transparent component, and configured to intercept sunlight, and a reflective component facing the optically transparent component and configured to reflect un-intercepted sunlight towards the bifacial solar cells. The bifacial cells are configured to be positioned with a first surface facing sunlight and a second surface facing the reflective component.

### DRAWINGS

These and other features, aspects, and advantages of the present invention will become better understood when the following detailed description is read with reference to the accompanying drawings in which like characters represent like parts throughout the drawings, wherein:

FIG. 1 illustrates an embodiment of the solar energy concentrator system using the concept of total internal reflection in conjunction with bifacial solar cells in accordance with aspects disclosed herein;

FIG. 2 illustrates another embodiment of the solar energy concentrator system using the concept of total internal reflection in conjunction with bifacial solar cells in accordance with aspects disclosed herein;

FIG. 3 illustrates another embodiment of the solar energy concentrator system using the concept of total internal reflection in conjunction with bifacial solar cells in accordance with aspects disclosed herein;

FIG. 4 illustrates an embodiment the solar energy concentrator system comprising an array of bifacial solar cells in accordance with aspects disclosed herein;

### DETAILED DESCRIPTION

Embodiments disclosed herein include solar energy concentrators. As used herein, singular forms such as “a,” “an,” and “the” include plural referents unless the context clearly dictates otherwise.

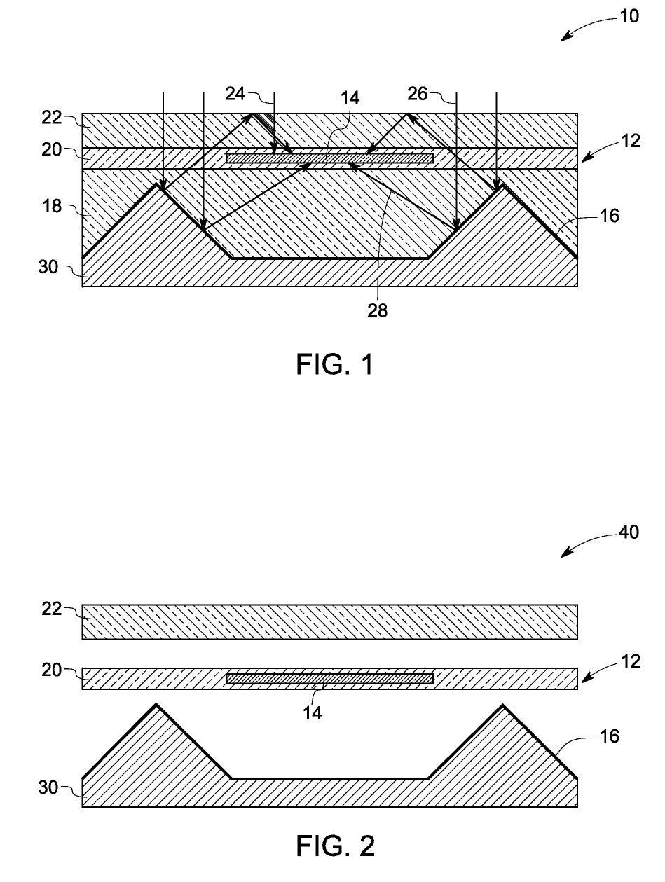

In one embodiment, as shown in FIG. 1, the solar energy concentrator system 10 comprises an optically transparent component 12, a bifacial solar cell 14, and a reflective component 16. The optically transparent component 12 further comprises, in a more specific embodiment, a first component 18 adjoining the reflective component, a second component 20 adjoining the first component, and a third component 22 adjoining the second component. The first, second and third components are optically transparent in the sense that they allow sunlight to pass through. The bifacial solar cell may be encapsulated in the second component 20, for example. In another embodiment, an encapsulated bifacial cell represents the second component and the bifacial cell.

The bifacial solar cell 14 is situated such that a first surface 13 of the bifacial solar cell 14 faces sunlight and a second surface 15 of the bifacial solar cell 14 faces the reflective component 16. The two surfaces of bifacial solar cell may have the same efficiency or different efficiencies. In an embodiment wherein the surfaces have different efficiencies, the bifacial solar cell 14 is situated such that a first surface with higher efficiency faces sunlight and a second surface with relatively lower efficiency faces the reflective component 16.

The reflective component 16 is situated so as to face the bifacial solar cell 14. The surface area of the bifacial solar cell 14 is less than the surface area of the solar energy concentrator system 10. The bifacial solar cell 14 is configured to intercept sunlight passing through the third component. However, only a portion of sunlight 24 is intercepted by the bifacial solar cell 14. The un-intercepted sunlight 26 will head toward the reflective component 16. The reflective component 16 is configured to reflect the un-intercepted sunlight 26 toward the first or second surface of the bifacial solar cell 14.

Not all sunlight reflected by the reflective component 16 can intercept the first or second surface the bifacial solar cell 14. Therefore, the third component 22 is configured to direct sunlight 28 that is reflected by the reflective component 16, and not intercepting the bifacial solar cell, towards the bifacial solar cell 14. The third component 22 and the reflective component 16 are also adapted to direct the sunlight (not shown) reflected from the bifacial solar cell back onto the bifacial solar cell 14. In effect, the reflective component 16 and the third component 22 together form a total internal reflection structure, reflecting sunlight within the system and directing sunlight toward the bifacial solar cell.

In another embodiment, to deal with technical challenges in making a complete total internal reflection structure, the third component 22 and the reflective component 16 can be configured to reflect the sunlight within the system as many times as possible. Therefore, the third component 22 and the reflective component 16 can be adapted to direct at least a part of sunlight reflected from the bifacial solar cell 14 and the reflective component 16 toward the bifacial solar cell 14.

The reflective component 16 may comprise a series of angled surfaces as shown in FIG. 1. However, other optical structures such as gratings and curved surfaces can also be employed for the reflective component 16 to form a total internal reflection structure or a structure that is capable of reflecting the sunlight within the system as many times as possible.

The third component 22 may also be configured to provide structural protection to the bifacial solar cell 14, and, in one embodiment, is configured to protect the bifacial solar cell from damage due to external elements. In one embodiment, the third component 22 comprises glass, the second component 20 comprises ethylene vinyl acetate, and the first component 18 comprises molded glass. The reflective component 16 may comprise a metal, for example, silver, coated on the bottom side of the first component 18. In another embodiment, the first component 18 comprises an optically transparent polymer and the reflective component 16 comprises a metal sheet supporting the first component 18. The third component comprising glass is laminated to second component 20, in one embodiment.

The system 10 further comprises a support structure 30 for the reflective component 16. The support structure 30 also provides structural support for the system 10. In one embodiment, the support structure comprises molded polymer. Alternately, the support structure can be integral to the reflective component 16.

In another embodiment 40 shown in FIG. 2, the second component 20 encapsulating a bifacial solar cell 14 is suspended between the third component 22 and the reflective plate 16. A gaseous medium (air) is in place of the first component 18 and/or in between the second component and the third component. The reflective component 16 and the third component 22 together form a total internal reflection structure, reflecting sunlight within the system and directing sunlight toward the bifacial solar cell. In this embodiment, the second component 20 includes any needed electrical connections (not shown).

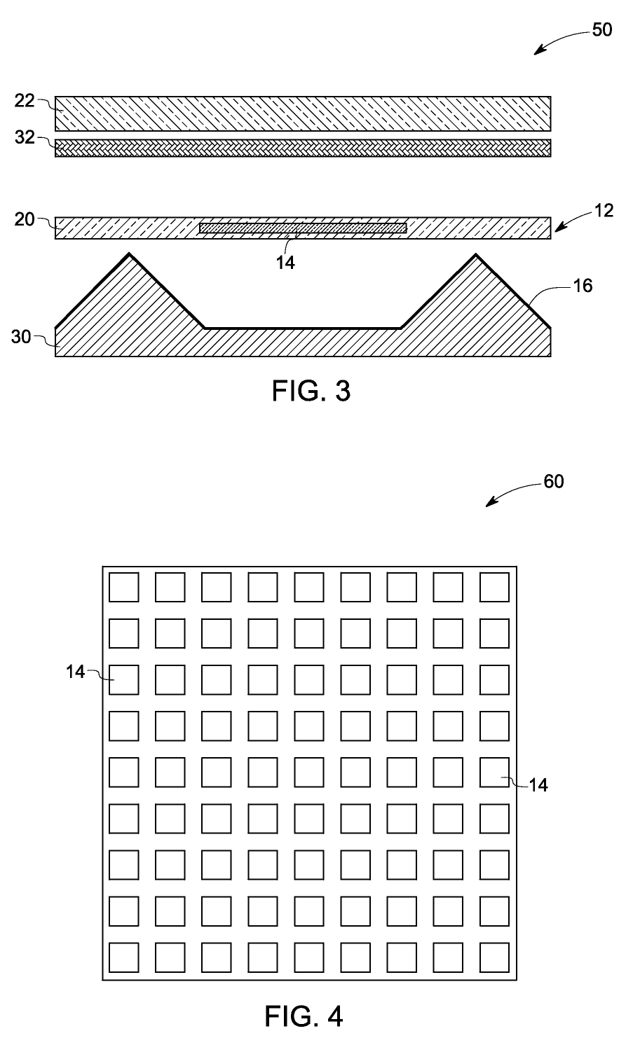

In another embodiment shown in FIG. 3, the solar energy concentrator system 50 additionally comprises a lens such as a Fresnel lens 32 configured to concentrate sunlight on to the bifacial solar cell 14. The lens is attached to the underside of the third component for protection. Appropriate spacing is maintained between the solar cell and the Fresnel lens 32 to provide required optical path for sunlight. The Fresnel lens 32 is made out of a polymer sheet in one embodiment. The surface area of the Fresnel lens 32 is greater the surface area of the solar cell so that the lens concentrates a larger area of the incident sunlight onto a smaller area of the solar cell. Employing a sunlight-concentrating lens 32 is expected to help in reduction of the size of the solar cell 14.

The bifacial solar cells 14 can be arranged in an array in the optically transparent component to form a larger solar energy concentrator system 60 as shown in FIG. 4. The bifacial solar cells 14 are spaced apart from each other in the solar energy concentrator system. Therefore, the total area of the solar energy concentrator system 60 is less than the total area of all the bifacial solar cells in solar energy concentrator system. In one embodiment, the total area of the bifacial solar cells is less than fifty percent of the total area of the solar energy concentrator system 10. The un-intercepted sunlight comprises sunlight passing through the spaces between the bifacial solar cells 14, which will be reflected by the reflective component toward the bifacial solar cells 14. The bifacial solar cells are typically equally spaced apart from each other and can be of different geometries with one example being a rectangular geometry.

The solar energy concentrator system 10, 40 and 50 may comprise a self-contained module. A plurality of solar energy concentrator systems 10, 40 and 50 can be arranged in an array packaged by clamping them together to form a high-level concentrator system, for example. The solar energy concentrator system 10 may additionally be designed as a planar structure. The planar configuration enables the solar energy concentrator system 10, 40 and 50 to be used anywhere a standard flat plate solar module is used. In one embodiment, the solar energy concentrator system 10, 40 and 50 can be used as built-in facades or other building integrated applications.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A solar energy concentrator system, comprising:
an optically transparent component;
a bifacial solar cell situated within the optically transparent component and configured to intercept sunlight; and
a reflective component configured to reflect un-intercepted sunlight towards the bifacial solar cell,
wherein the bifacial cell is configured to be positioned with a first surface facing sunlight and a second surface facing the reflective component.

2. The system of claim 1, wherein the optically transparent component comprises:
a first component adjoining the reflective component;
a second component adjoining the first component, wherein the bifacial solar cell is encapsulated in the second component; and
a third component adjoining the second component.

3. The system of claim 2, wherein the third component is configured for structural protection of the bifacial cell.

4. The system of claim 2, wherein the third component comprises glass.

5. The system of claim 4, wherein the second component comprises ethylene vinyl acetate.

6. The system of claim 5, wherein the first component comprises molded glass.

7. The system of claim 6, wherein the reflective component comprises metal coated on the first component.

8. The system of claim 2, wherein the reflective component comprises a metal sheet.

9. The system of claim 8, wherein the first component comprises a transparent polymer.

10. The system of claim 8, wherein the first component comprises a gaseous medium.

11. The system of claim 2, wherein the reflective component and the third component together form a total internal reflection structure.

12. The system of claim 1, wherein the optically transparent component and the reflective component are adapted to direct at least a part of the sunlight reflected from the bifacial cell back onto the bifacial cell.

13. The system of claim 1, further comprising a support structure for the reflective component.

14. The system of claim 1, wherein the system comprises a planar structure.

15. The system of claim 1, wherein the reflective component is angled.

16. The system of claim 1, further comprises a lens configured to concentrate sunlight on to the solar cell.

17. A solar energy concentrator system, comprising:
an optically transparent component;
bifacial solar cells arranged in an array, situated in the optically transparent component, and configured to intercept sunlight; and
a reflective component facing the optically transparent component and configured to reflect un-intercepted sunlight towards the bifacial solar cells,
wherein the bifacial cells are configured to be positioned with a first surface facing sunlight and a second surface facing the reflective component.

18. The system of claim 17, wherein the optically transparent component comprises:
a first component adjoining the reflective component;
a second component adjoining the first component, wherein the plurality of bifacial solar cells are encapsulated in the second component; and
a third component adjoining the second component.

19. The system of claim 18, wherein the third component is configured for structural protection of the bifacial cells.

20. The system of claim 17, wherein the total area of the bifacial solar cells is less than fifty percent of the total area of the solar energy concentrator system.

21. The system of claim 17, wherein solar energy concentrator system is a self-contained module.

22. The system of claim 21, wherein a plurality of the solar energy concentrator systems are arranged in an array.
